(19) United States
(12) Patent Application Publication
(10) Pub. No.: US 2025/0176314 A1
(43) Pub. Date: May 29, 2025

(54) LIGHT-EMITTING DEVICE AND METHOD FOR MANUFACTURING THEREOF

(71) Applicant: XIAMEN SAN'AN OPTOELECTRONICS CO., LTD., Xiamen (CN)

(72) Inventors: MISAICHI TAKEUCHI, Xiamen (CN); Zhongjie YANG, Xiamen (CN); KUO-HUA CHANG, Xiamen (CN); YUNGLING LAN, Xiamen (CN); JING-FENG HUANG, Xiamen (CN)

(21) Appl. No.: 19/031,027

(22) Filed: Jan. 17, 2025

Related U.S. Application Data
(63) Continuation-in-part of application No. PCT/CN2022/130857, filed on Nov. 9, 2022.

(51) Int. Cl. H10H 20/815; H10H 20/01; H10H 20/825

(52) U.S. Cl. CPC H10H 20/815; H10H 20/0137; H10H 20/017; H10H 20/825

(57) ABSTRACT

A method for manufacturing a light-emitting device includes steps of providing a substrate, the substrate having a first surface and a second surface that are opposite to each other; forming a nucleation layer on the first surface of the substrate by deposition, the nucleation layer having an upper surface that is uneven; forming a plurality of first voids, the plurality of first voids extending in a direction from the nucleation layer to the substrate, each of the plurality of first voids having an aspect ratio that is greater than 1, and a diameter that is no greater than 300 nm; forming an AlₓGa₁₋ₓN layer on the nucleation layer to form an even surface, x>0.5; and forming a semiconductor epitaxial structure on the AlₓGa₁₋ₓN layer. A light-emitting device manufactured by the above method is also provided.

### CROSS-REFERENCE TO RELATED APPLICATION

This application is a continuation-in-part (CIP) of International Application No. PCT/CN2022/130857, filed on Nov. 9, 2022, the entire disclosure of which is incorporated by reference herein.

### FIELD

The disclosure relates to semiconductor technology, and more particularly to a light-emitting device and a manufacturing method thereof.

### BACKGROUND

Nitride semiconductors exhibit excellent thermal stability and wide bandgap energy, thereby drawing attentions in the field of optical devices and high power electronics. Specifically, blue, green and ultraviolet (UV) light-emitting devices having nitride semiconductors therein have been commercialized and are widely used.

In particular, light-emitting devices that emit light in a UV wavelength range may be used for material curing and sterilization. A conventional UV light-emitting device often includes a relatively thick AlₓGa₁₋ₓN layer disposed between a substrate and an active layer to reduce lattice mismatch between the active layer and the substrate. However, difference between lattice constants of the substrate and the AlₓGa₁₋ₓN layer is still large, so dislocation density is greater than 1E10⁹ cm⁻² in an epitaxial structure of the conventional UV light-emitting device, thereby lowering light output efficiency of the conventional UV light-emitting device. However, due to a difference in thermal expansion coefficients between the substrate and the epitaxial structure, cracks may easily be formed with the relatively thick AlₓGa₁₋ₓN layer.

At the same time, due to total reflection between a buffer layer and the substrate, light extraction efficiency of the conventional UV light-emitting device may decrease. To improve the light extraction efficiency, forming air voids has been attempted. However, it is difficult to control formation of the air voids.

### SUMMARY

Therefore, an object of the disclosure is to provide a light-emitting device and a method for manufacturing thereof that can alleviate at least one of the drawbacks of the prior art.

According to a first aspect of the disclosure, the method for manufacturing a light-emitting device includes providing a substrate, the substrate having a first surface and a second surface that are opposite to each other; forming a nucleation layer on the first surface of the substrate by deposition, the nucleation layer having an upper surface that is uneven; forming a plurality of first voids, the plurality of first voids extending in a direction from the nucleation layer to the substrate, each of the plurality of first voids having an aspect ratio that is greater than 1, and a diameter that is no greater than 300 nm; forming an AlₓGa₁₋ₓN layer on the nucleation layer to form an even surface, x>0.5; and forming a semiconductor epitaxial structure on the AlₓGa₁₋ₓN layer.

According to a second aspect of the disclosure, the light-emitting device includes a substrate, a nucleation layer, an AlₓGa₁₋ₓN layer, and a semiconductor epitaxial structure. The substrate has a first surface and a second surface that are opposite to each other. The nucleation layer is formed on the first surface of the substrate and has an upper surface that is uneven. The AlₓGa₁₋ₓN layer is formed on the nucleation layer and has an upper surface that is even and x>0.5. The semiconductor epitaxial structure is formed on the AlₓGa₁₋ₓN layer. The light-emitting device further includes a plurality of first voids. The plurality of first voids extend in a direction from the nucleation layer to the substrate. Each of the plurality of first voids has an aspect ratio that is greater than 1, and a diameter that is no greater than 300 nm.

According to a third aspect of the disclosure, a light-emitting device includes a substrate, a nucleation layer, an AlₓGa₁₋ₓN layer, and a semiconductor epitaxial structure. The substrate has a first surface and a second surface that are opposite to each other. The nucleation layer is formed on the first surface of the substrate and has an upper surface that is uneven. The AlₓGa₁₋ₓN layer is formed on the nucleation layer and has an upper surface that is even, x>0.5. The semiconductor epitaxial structure is formed on the AlₓGa₁₋ₓN layer. The substrate is formed with a plurality of first voids that are proximate to the first surface. Each of the plurality of first voids forms a needle-like structure, and has an end that contacts the first surface and another end that extends towards the second surface. Each of the plurality of first voids has a diameter that is greater than 0 and smaller than 100 nm. The AlₓGa₁₋ₓN layer is formed with a plurality of second voids that are distributed in the AlₓGa₁₋ₓN layer.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a cross-sectional view of an embodiment of a light-emitting device according to the disclosure.

FIG. 2 is a partially enlarged schematic view of FIG. 1 illustrating first voids and second voids.

FIG. 3 is a flow chart illustrating a method for manufacturing the light-emitting according to the disclosure.

FIGS. 4-11 illustrate steps of the method for manufacturing the light-emitting according to the disclosure.

FIG. 12 is a transmission electron microscope (TEM) image of the embodiment of the light-emitting device according to the disclosure.

FIG. 13 is a cross-sectional view of another embodiment of the light-emitting device according to the disclosure.

FIG. 14 is a partially enlarged schematic view of FIG. 13 illustrating the first voids and the second voids.

FIG. 15 is a top view of still another embodiment of the light-emitting device according to the disclosure.

FIG. 16 is a cross-sectional view of FIG. 15.

FIG. 17 is a schematic view of a light-emitting apparatus according to the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

The following embodiments of the disclosure disclose a light-emitting device having a substrate, a semiconductor epitaxial structure disposed on the substrate, and a plurality of microvoids each disposed between material layers having different refractive indices. Each of the microvoids has an aspect ratio greater than 1, and a diameter no greater than 300 nm. In an embodiment, the microvoids may be located at least in two material layers having different refractive indices at the same time. For example, each of the microvoids may have one end contacting a surface of the substrate and another end located in a semiconductor layer. The microvoids are connected to the semiconductor layer and the substrate at the same time, thereby significantly reducing dislocation density of the semiconducting epitaxial structure. Furthermore, the microvoids located in an AlₓGa₁₋ₓN layer may release stress in the semiconductor epitaxial structure and prevent generation of cracks, thereby improving lattice quality of the semiconductor epitaxial structure.

Each of the microvoids has a needle-like configuration, may provide a stable nucleation surface for lateral epitaxy of an AlN material or an AlGaN material, and may reduce dislocation density of the AlₓGa₁₋ₓN layer while decreasing thickness of lateral epitaxy of the AlₓGa₁₋ₓN layer, thereby improving epitaxial efficiency.

The microvoids formed between the substrate and the semiconductor epitaxial structure may scatter light and enhance light coupling between the substrate and the semiconductor epitaxial structure, so that light waves trapped in the semiconductor epitaxial structure may enter the substrate and exit outwardly from the substrate. The microvoids located in the AlₓGa₁₋ₓN layer may reduce total reflection in the light-emitting device and improve light extraction efficiency of thereof.

The diameter of each of the microvoids ranges from 2 nm to 100 nm and a distance between two adjacent ones of the microvoids is smaller than 1 μm, thereby allowing light extraction of short wavelength light (e.g., light extraction of an UV light-emitting device). The microvoids are similar to each other and uniform in size and shape, which allows the light-emitting device to emit stable and uniform light and prevents large variations in light extraction efficiency.

The semiconductor epitaxial structure of the light-emitting device may include an n-type nitride semiconductor, an active layer including a nitride semiconductor material, and a p-type nitride semiconductor layer. The light-emitting device may emit light in the ultraviolet (UV) wavelength range. For example, the light-emitting device may emit light in a near UV wavelength range (UV-A), in a far UV wavelength range (UV-B), or in a deep UV wavelength range (UV-C). The wavelength range depends on compositions of the active layer. For example, the light in the near UV wavelength range (UV-A) may have a wavelength that ranges from 320 nm to 420 nm, the light in the far UV wavelength range (UV-B) may have a wavelength that ranges from 280 nm to 320 nm, and the light in the deep UV wavelength range (UV-C) may have a wavelength that ranges from 100 nm to 280 nm. When a group III nitride semiconductor is used, the light-emitting device may emit light having a short wavelength that is smaller than 450 nm.

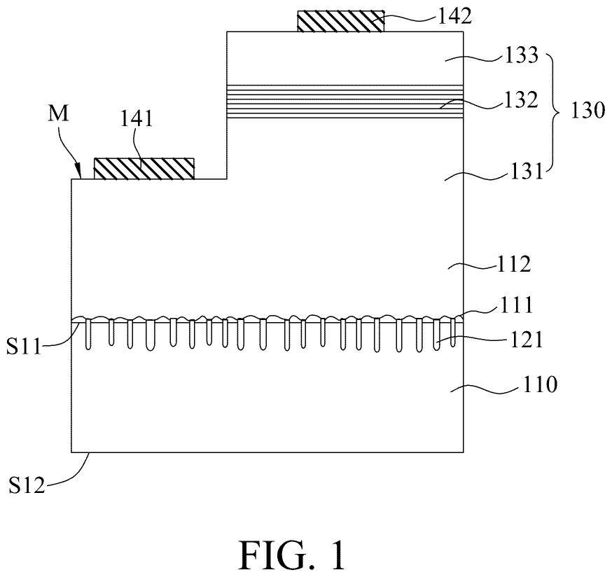

Referring to FIG. 1, an embodiment of a light-emitting device according to the disclosure is provided. Referring to FIG. 1, the light-emitting device includes a substrate 110, a nucleation layer 111, an AlₓGa₁₋ₓN layer 112, a semiconductor epitaxial structure 130, a first contact electrode 141, and a second contact electrode 142. A plurality of first voids 121 are formed between or located in the substrate 110 and the AlₓGa₁₋ₓN layer 112. The semiconductor epitaxial structure 130 includes a first semiconductor layer 131 (an n-type semiconductor layer), an active layer 132, and a second semiconductor layer 133 (a p-type semiconductor layer). The first contact electrode 141 is electrically connected to the first semiconductor layer 131, and the second contact electrode 142 is electrically connected to the second semiconductor layer 133. The semiconductor epitaxial structure 130 may emit light in a UV wavelength range. For example, the semiconductor epitaxial structure 130 may emit light in the near ultraviolet wavelength range (UV-A), in the far ultraviolet wavelength range (UV-B), or in the deep ultraviolet wavelength range (UV-C). The UV wavelength range of the light emitted by the semiconductor epitaxial structure 130 depends on an aluminum content of the semiconductor epitaxial structure 130.

The substrate 110 serves to support the semiconductor epitaxial structure 130. The substrate has a first surface (S11) and a second surface (S12) that are opposite to each other. The semiconductor epitaxial structure 130 is formed on the first surface (S11). The substrate 110 is, for example, a sapphire substrate, and may also be a growth substrate for forming a group III nitride semiconductor film. The group III nitride semiconductor may include SiC, Si, GaAs, GaN, ZnO, GaP, InP, Ge, Ga₂O₃, or combinations thereof.

The nucleation layer 111 is formed on the first surface (S11) of the substrate 110, may reduce lattice mismatch between the substrate 100 and the semiconductor epitaxial structure 130 which is to be formed in a subsequent process, and may have a thickness that ranges from 2 nm to 20 nm. The nucleation layer 111 may include a III-V compound semiconductor material such as GaN, InN, AlN, InGaN, AlGaN, InAlGaN, AlInN, or combinations thereof. In an embodiment, the nucleation layer 111 may be an AlN layer formed on the substrate 110 by physical vapor deposition (PVD), and may have a thickness that ranges from 1 nm to 10 nm. The nucleation layer 111 may further be subjected to a high-temperature treatment and has an upper surface that is uneven. An AlₓGa₁₋ₓN layer 112 is formed on the nucleation layer 111 for moderating the lattice mismatch between the semiconductor epitaxial structure 130 and the substrate 110. The AlₓGa₁₋ₓN layer 112 may have a thickness that ranges from 500 nm to 3 μm and may be a single layered or a multilayered structure such as an AlN structure or an AlGaN/AlN superlattice structure.

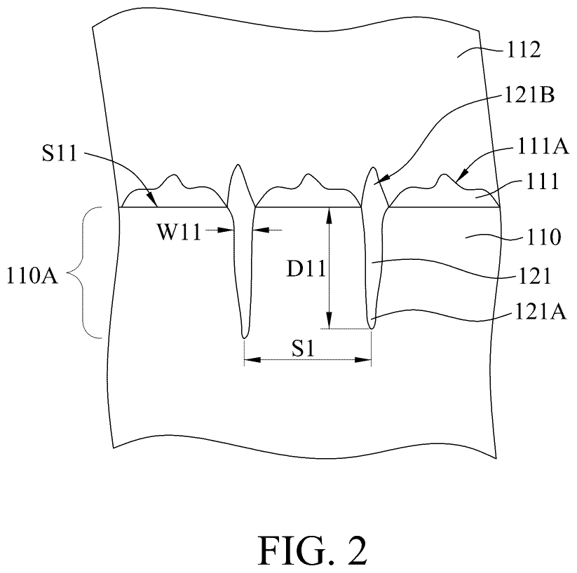

Referring to FIGS. 1 and 2, FIG. 2 is a partially enlarged schematic view of FIG. 1. The first voids 121 are spaced apart from and parallel to each other, and are formed between a top portion 110A of the substrate 110 and the AlₓGa₁₋ₓN layer 112. Each of the first voids 121 has at least a lower end portion 121A that extends in a direction from an upper surface 111A of the nucleation layer 111 to a certain depth in the substrate 110. Furthermore, by virtue of lateral epitaxial growth of the AlₓGa₁₋ₓN layer 112, each of the first voids 121 also has an upper end portion 121B that extends into the AlₓGa₁₋ₓN layer 112 to a certain depth, such that the first voids 121 may be connected to both the substrate 110 and the AlₓGa₁₋ₓN layer 112 at the same time.

In some embodiments, the first voids 121 are densely distributed in the top portion 110A of the substrate 110, which, in combination with the AlₓGa₁₋ₓN layer 112 formed by lateral epitaxy, may reduce the dislocation density of the AlₓGa₁₋ₓN layer 112 and improve the lattice quality of the semiconductor epitaxial structure 130. Furthermore, each of the first voids 121 has a diameter no greater than 300 nm, provides a stable nucleation surface for the lateral epitaxy of the AlₓGa₁₋ₓN layer 112, reduces thickness of the lateral epitaxy of the AlₓGa₁₋ₓN layer 112, and improves the epitaxial efficiency. Due to lateral epitaxial growth ability of the AlGaN material and the AlN material being much lower than lateral epitaxial growth ability of a GaN material, when the diameter of each of the first voids 121 is greater, the thickness of the AlₓGa₁₋ₓN layer 112 needs to be increased so as to provide the AlₓGa₁₋ₓN layer 112 with an even surface fully closing the first voids 121. In an embodiment, the diameter of each of the first voids 121 is smaller than 100 nm (e.g., ranging from 5 nm to 90 nm), and a distance (S1) between two adjacent ones of the first voids 121 is smaller than 1 μm. In some embodiments, the distance (S1) is smaller than 500 nm (e.g., ranging from 10 nm to 200 nm), so that the AlₓGa₁₋ₓN layer 112 may have an even surface while having a thickness smaller than 2 μm. In some embodiments, each of the first voids 121 has an aspect ratio that is greater than 1, which may reduce the diameter of each of the first voids 121 while increasing a depth (D11) of each of the first voids 121 in the top portion (110A) of the substrate 110, thereby effectively increasing volume of the first voids 121 while keeping the first voids 121 small-sized, which may facilitate moderating stress of the AlₓGa₁₋ₓN layer 112. In other embodiments, the aspect ratio of each of the first voids 121 may be no smaller than 2; the first voids 121 resemble fine needles that are distributed in the top portion (110A) of the substrate 110, which may release the stress in the semiconductor epitaxial structure 130 while also reducing the total reflection in the light-emitting device. In some embodiments, the depth (D11) of each of the first voids 121 in the substrate 110 may range from 20 nm to 500 nm. In other embodiments, the depth (D11) of each of the first voids 121 in the substrate 110 may be greater than 50 nm and no greater than 2000 nm.

In some embodiments, the first voids 121 are similar to each other and uniform in size and shape. The diameter of each of the first voids 121 ranges from 10 nm to 100 nm, and the distance (S1) between two adjacent ones of the first voids 121 is smaller than 1 μm, which allows for the light extraction of short wavelength light (e.g., light of an UV light-emitting device).

The semiconductor epitaxial structure 130 is formed on the AlₓGa₁₋ₓN layer 112, made of the group III nitride semiconductor, and includes the first semiconductor layer 131, the active layer 132, and the second semiconductor layer 133.

The first semiconductor layer 131 includes a material that is represented by Alₓ₁In_{y1}Ga_{z1}N, where x1, y1, and z1 satisfy the following formulas: 0<x1≤1.0, 0≤y1≤0.1, 0≤z1<1, and x1+y1+z1=1. In some embodiments, the first semiconductor layer 131 has a doping concentration that ranges from 1.0×10¹⁷/cm³ to 1.0×10²⁰/cm³, and a thickness that ranges from 500 nm to 3 μm. The active layer 132 emits light having a specific wavelength, and may be a multiple quantum well structure including well layers and barrier layers that are alternately stacked. Each of the well layers has a thickness that is greater than 1 nm. In some embodiments, the thickness of each of the well layers is greater than 2 nm. Each of the barrier layers has a thickness that is greater than 1 nm. In some embodiments, the thickness of each of the barrier layers is greater than 2 nm. The second semiconductor layer 133 includes a p-type cladding layer and a p-type contact layer. The p-type cladding layer includes a material that is represented by Alₓ₂In_{y2}Ga_{z2}N, where x2, y2, and z2 satisfy the following formulas: 0<x2≤1.0, 0≤y2≤0.1, and 0≤z2<1.0, and x2+y2+z2=1. In some embodiments, the p-type cover layer has a greater bandgap that that of the active layer 132, which may keep electrons in the active layer 132. Thus, in some embodiments, an aluminum content of the p-type cladding layer is greater than an aluminum content of the active layer 132. Furthermore, the p-type cladding layer is doped with Mg, and has a doping concentration that is greater than 1.0×10¹⁷/cm³ and a thickness that ranges from 5 nm to 1000 nm. In some embodiments, the doping concentration of the p-type cladding layer is greater than 1.0×10¹⁸/cm³. The p-type contact layer includes a material that is represented by Alₓ₃In_{y3}Ga_{z3}N, where x3, y3, and z3 satisfy the following formulas: 0<x3≤1.0, 0≤y3≤0.1, 0≤z3<1, and x3+y3+z3=1. In some embodiments, an aluminum content of the p-type contact layer is smaller than that of the p-type cladding layer, thereby facilitating a good contact. The p-type contact layer is doped with Mg, and has a doping concentration that is greater than 1.0×10¹⁷/cm³, and a thickness that ranges from 1 nm to 30 nm; this facilitates transmittance of UV light and contact characteristics of the p-type contact layer.

A portion of the second semiconductor layer 133 and a portion of the active layer 132 are removed to expose the first semiconductor layer 131, thereby forming at least one mesa surface (M). The first contact electrode 141 is disposed on the mesa surface (M) and is electrically connected to the first semiconductor layer 131. The second contact electrode 142 is disposed on and electrically connected to the p-type contact layer. In an embodiment, the first contact electrode 141 is in contact with the mesa surface (M), and forms an ohmic contact with the first semiconductor layer 131. The first contact electrode 141 may be made of Cr, Pt, Au, Ni, Ti, Al, or combinations thereof. Since the first semiconductor layer 131 has a high aluminum content, the first contact electrode 141 needs to be fused at high temperature to form into an alloy so as to form a good ohmic contact with the first semiconductor layer 131. The first contact electrode 141 may be a Ti/Al/Au/Pt alloy, a Ti/Al/Ni/Au alloy, a Cr/Al/Ti/Au alloy, etc. The second contact electrode 142 is in contact with the p-type contact layer. The second contact electrode 142 may be made of a transparent conductive oxide material or a metal alloy such as NiAu, NiAg, NiRh, etc., and has a thickness of smaller than 30 nm, so as to reduce light absorption. In an embodiment, the active layer 132 emits light that has a wavelength smaller than 280 nm. The second contact electrode 142 is made of ITO, and has a thickness that ranges from 5 nm to 20 nm, specifically, from 10 nm to 15 nm. The second contact electrode 142 may reduce light absorption of the light emitted by the active layer 132 to be less than 40%.

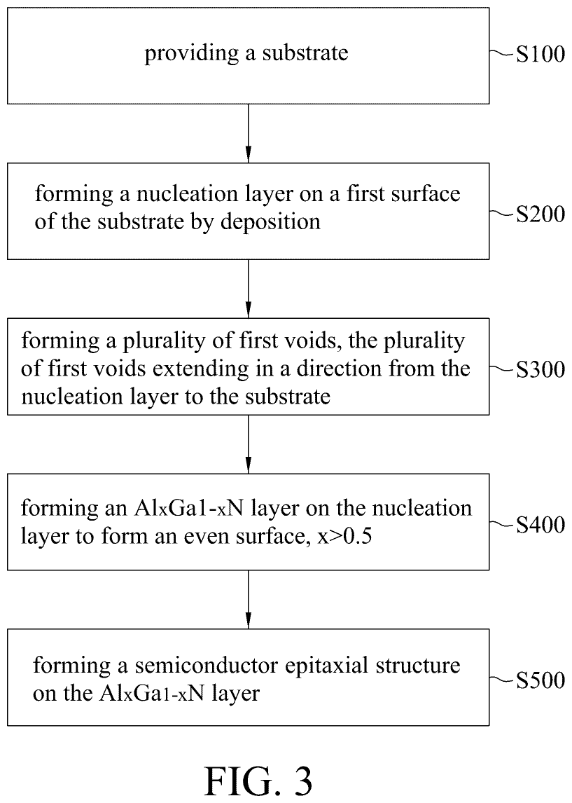

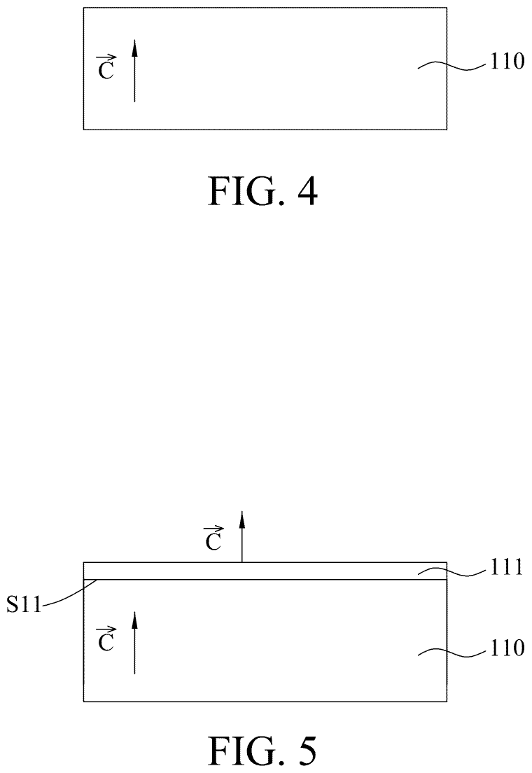

FIG. 3 is a flow chart illustrating a method for manufacturing the light-emitting device according to the disclosure. The method includes steps S100 to S500 and will be described in combination with FIGS. 4 to 11 in detail.

First, the substrate 110 is provided for epitaxial growth, and has the first surface (S11) and the second surface (S12) that are opposite to each other. The substrate 110 may be a sapphire substrate. Referring to FIG. 4, the substrate 110 has a common C-axis orientation.

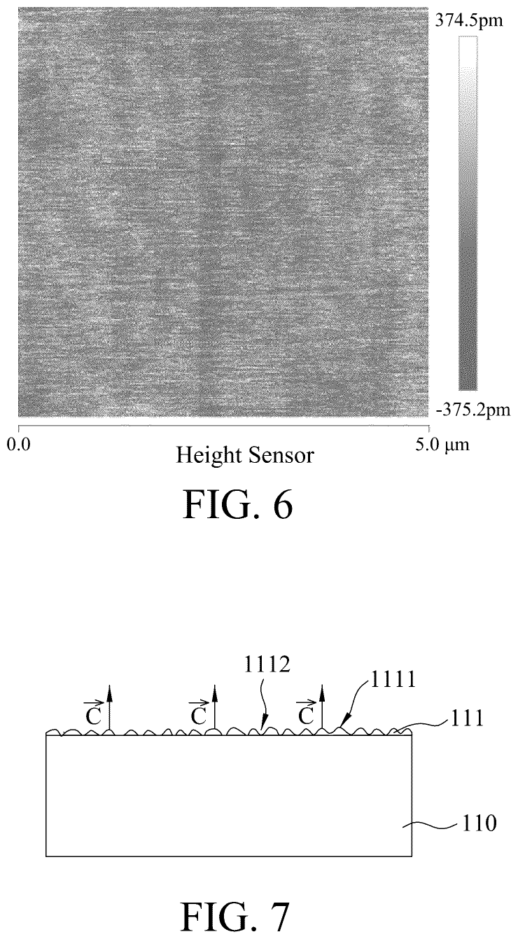

Next, the nucleation layer 111 is formed on the first surface (S11) of the substrate 110 by deposition (step S200). As an example, an AlN layer having a thickness that ranges from 1 nm to 10 nm may be formed as the nucleation layer 111 on the first surface (S11) of the substrate 110 made of sapphire, as shown in FIG. 5. A plurality of high-density dislocations are automatically formed in the nucleation layer 111. In an embodiment, the AlN layer is formed on the first surface (S11) of the substrate 110 as the nucleation layer 111 by physical vapor deposition (PVD). FIG. 6 shows an AFM (Atomic Force Microscope) image of the AlN layer formed on the first surface (S11) of the substrate 110 using PVD. As can be seen, the AlN layer has a relatively even surface with a surface roughness (Ra) of 0.085 nm.

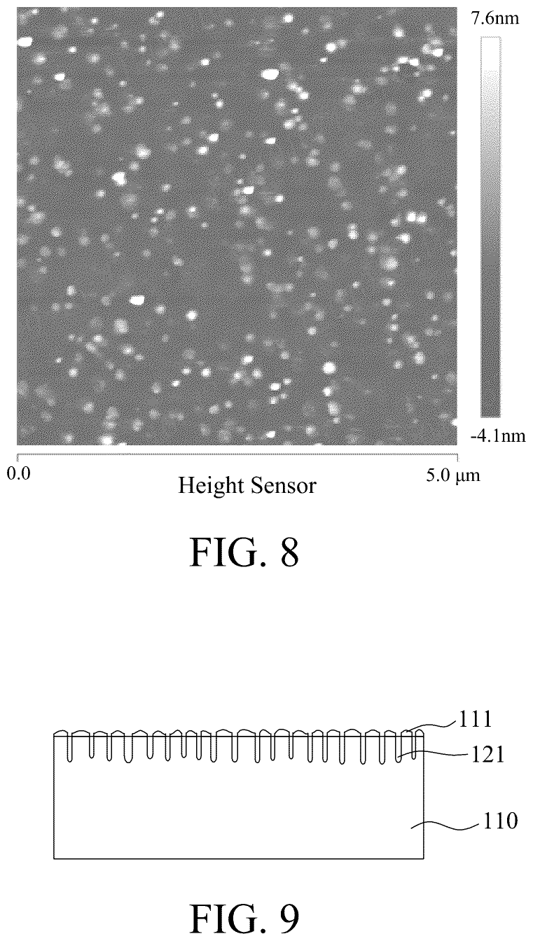

Then, the plurality of first voids 121 are formed. The first voids 121 extend in the direction from the nucleation layer 111 to the substrate 110 (step S300). In an embodiment, the nucleation layer 111 is subjected to a high-temperature treatment to form a plurality of islands 1111. A plurality of pinholes 1112 are formed between adjacent ones of the islands 1111. The islands 1111 are parallel to each other along the C-axis as shown in FIG. 7. Specifically, the islands 1111 and the atomic-sized pinholes 1112 are formed after the nucleation layer 1111 is subjected to a high-temperature treatment for several minutes using a mixture of H₂ and NH₃ gases at a temperature greater than 1100° C. During the high-temperature treatment, the mixture of the gases etches the substrate 110, thereby forming the first voids 121 each having the needle-like structure, as shown in FIG. 9. In some embodiments, the diameter of each of the first voids 121 is no greater than 300 nm. In some embodiments, the diameter of each of the first voids 121 is smaller than 100 nm. FIG. 8 shows an AFM image of the nucleation layer 111 after the high-temperature treatment. The nucleation layer 111 no longer has an even surface (i.e., the upper surface thereof is uneven) after the high-temperature treatment, and has an average surface roughness of 1.04 nm.

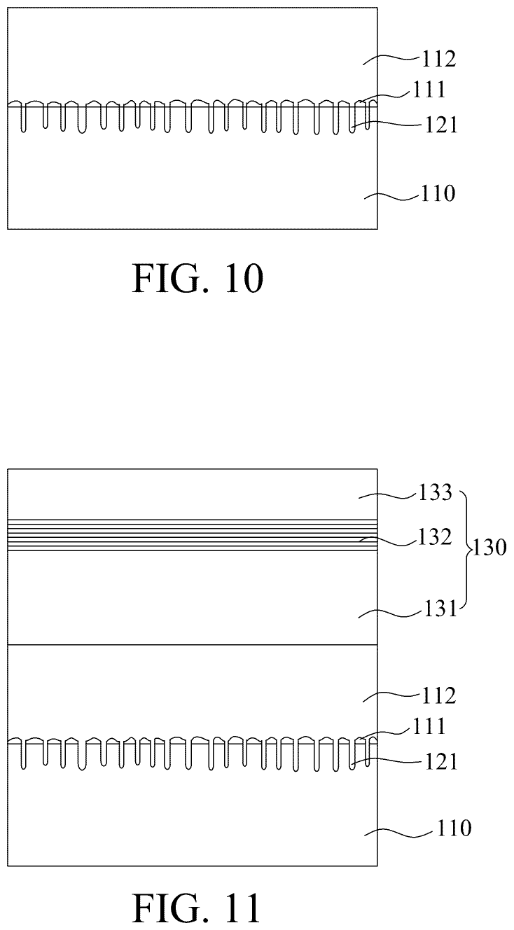

Then, the AlₓGa₁₋ₓN layer 112 is formed on the nucleation layer 111 to form an even surface (step S400), as shown in FIG. 10. Specifically, the AlₓGa₁₋ₓN layer 112 having a thickness of at least several hundred nanometers may be formed on the nucleation layer 111 by methods such as metal-organic chemical vapor deposition (MOCVD), metal-organic vapor phase epitaxy (MOVPE), molecular beam epitaxy (MBE), and hydride vapor phase epitaxy (HVPE), and the even surface may be obtained by lateral epitaxial growth. In an embodiment, the AlₓGa₁₋ₓN layer 112 has an aluminum content of X>0.5, and a thickness that ranges from 500 nm to 3 μm, and may be a single-layered or a multilayered structure such as an AlN structurer an AlGaN/AlN superlattice structure. In this embodiment, each of the first voids 12a has the needle-like structure that extends in a vertical direction. On one hand, the first voids 121 provide a stable nucleation surface 111 for the lateral epitaxial growth of the AlₓGa₁₋ₓN layer 112, so that the AlₓGa₁₋ₓN layer 112 may quickly form a slit-free even surface that closes above the first voids 121, thereby reducing the thickness of the AlₓGa₁₋ₓN layer 112, and enhancing epitaxy efficiency. On the other hand, the first voids 121 are formed from the dislocations in the nucleation layer 111. The first voids 121 interconnects the substrate 110 and the AlₓGa₁₋ₓN layer 112, may reduce density of dislocations in the AlₓGa₁₋ₓN layer 112, and releases the stress in the semiconductor epitaxial structure 130, thereby preventing cracks to be generated and improving the lattice quality of the semiconductor epitaxial structure 130. In some embodiments, the thickness of the AlₓGa₁₋ₓN layer 112 ranges from 500 nm to 2 μm.

Then, the semiconductor epitaxial structure 130 is formed on the AlₓGa₁₋ₓN layer 112 (step S500), as shown in FIG. 11. The semiconductor epitaxial structure 130 is made of the group III nitride semiconductor, and includes the first semiconductor layer 131, the active layer 132, and the second semiconductor layer 133

Finally, the first contact electrode 141 and the second contact electrode 142 are disposed on the semiconductor epitaxial structure 130, as shown in FIG. 1. Specifically, the portion of each of the first semiconductor layer 131, and the active layer 132, and the second semiconductor layer 133 may be removed by etching to expose the mesa surface (M). Then, the first contact electrode 141 is disposed on the mesa surface (M), and the second contact electrode 142 is disposed on the p-type contact layer of the second semiconductor layer 133.

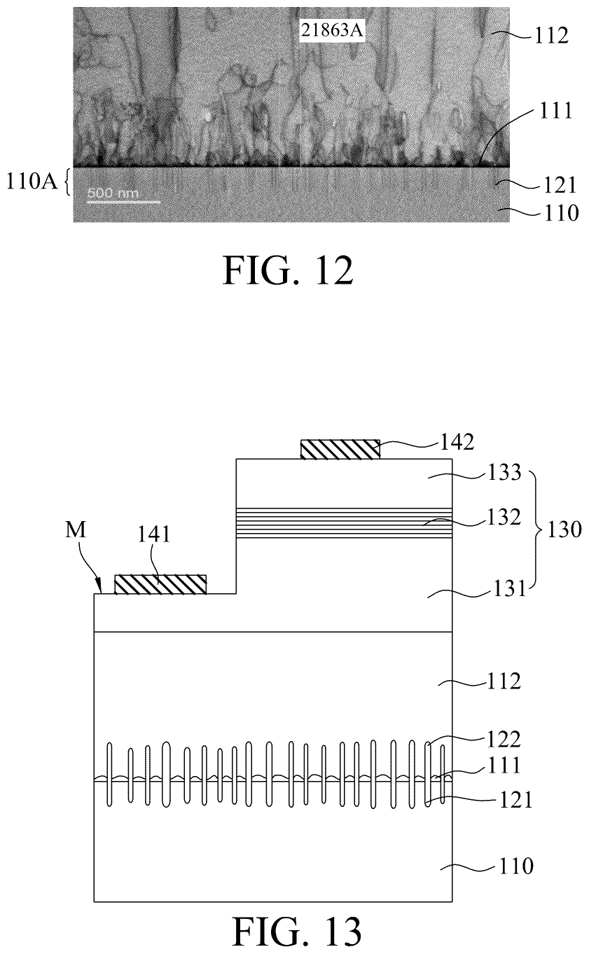

FIG. 12 shows a transmission electron microscope (TEM) image of a portion of the light-emitting device formed using the abovementioned method. As can be seen from FIG. 12, the first voids 121 that have the needle-like structures are distributed in the top portion 110A of the substrate 110. The first voids 121, although randomly distributed, have approximately the same structures and are substantially densely distributed in the top portion 110A of the substrate in a relatively uniform manner. The diameter of each of the first voids 121 is smaller than 100 nm, and the aspect ratio of each of the first voids 121 is greater than 1. The distance between two adjacent ones of the first voids 121 is smaller than 500 nm. The first voids 121 are approximately the same in shapes and sizes, thereby allowing light extraction for the UV light-emitting device, being conducive to emit stable and uniform light, and preventing large variations in the light extraction efficiency.

FIG. 13 illustrates another embodiment of the light-emitting device according to the present disclosure. The components in this embodiment identical to those in the embodiment shown in FIG. 1 will be given the same reference numbers, and descriptions of repeated components thereof will be omitted. The present embodiment has substantially the same structure as that shown in FIG. 1, except that this embodiment of the light-emitting device further includes a plurality of second voids 122 that are formed in a bottom portion 112A of the AlₓGa₁₋ₓN layer 112 that is proximate to the substrate 110.

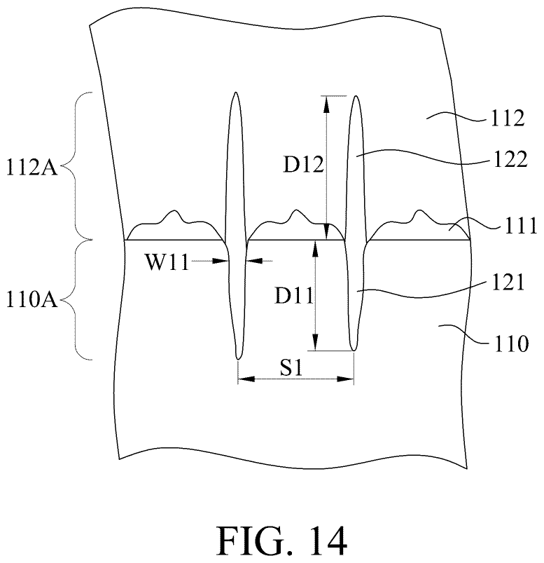

FIG. 14 illustrates an enlarged sectional view of the first voids 121 and the second voids 122 shown in FIG. 13. Referring to FIG. 14, the first voids 121 are formed in the top portion 110A of the substrate 110 and the second voids 122 are formed in the bottom portion 112A of the AlₓGa₁₋ₓN layer 112. The first voids 121 are similar to the first voids 121 shown in FIG. 1. The second voids 121 may respectively extend from the first voids 121 along the C-axis, and each having a diameter proximately similar to the diameter (W11) of each of the first voids 121. In other embodiments, some of the second voids 122 may be formed by combining two or more adjacent ones of the first voids 121. In some embodiments, each of the second voids 122 has a depth (D12) that is greater than the depth (D11) of each of the first voids 121. The depth (D12) of each of the second voids 122 may be greater than 100 nm. This second voids 122 may be formed by controlling growth conditions of the AlₓGa₁₋ₓN layer 112 for forming the needle-like structures. In an embodiment, the depth (D11) of each of the first voids 121 may range from 50 nm to 300 nm, and the depth (D12) of each of the second voids 122 may range from 100 nm to 1000 nm (e.g., ranging from 300 nm to 800 nm), which is conducive to the AlₓGa₁₋ₓN layer 112 to form a slit-free even surface on the second voids 122 after the AlₓGa₁₋ₓN layer 112 grows to a certain thickness, and which may facilitate epitaxial growth efficiency and electroluminescence performance of the light-emitting device. A distance between each of the second voids 122 and a bottom surface of the second semiconductor layer 131 may be no smaller than 500 nm. First, a first sublayer having a first thickness of the AlₓGa₁₋ₓN layer 112 is formed on the nucleation layer 111, then a second sublayer having a second thickness is formed on the first sublayer. Such design may improve lattice quality of the AlₓGa₁₋ₓN layer 112. The first sublayer of the AlₓGa₁₋ₓN layer 112 may improve the lattice quality of the AlₓGa₁₋ₓN layer 112, and the second sublayer of the AlₓGa₁₋ₓN layer 112 may ensure the slit-free even surface is formed above the second voids 122.

In this embodiment, the second voids 122 in the AlₓGa₁₋ₓN layer 112 not only release the stress in the semiconductor epitaxial structure 130, but may also reduce the total reflection in the light-emitting device, thereby improving the light extraction efficiency of the light-emitting device.

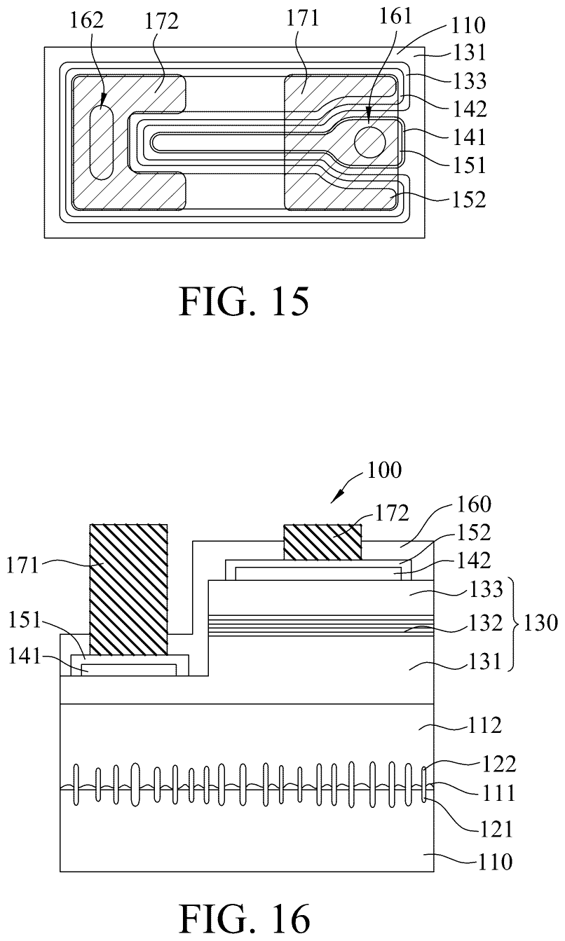

FIGS. 15 and 16 illustrate still another embodiment of the light-emitting device 100 according to the present disclosure. FIG. 15 is a top view and FIG. 16 is a sectional view of this embodiment of the light-emitting device 100. The components in this embodiment identical to those in the embodiment shown in FIG. 1 will be given the same reference numbers, and descriptions of the components thereof will be omitted. The present embodiment has substantially the same structure as that of the light-emitting device shown in FIG. 13, except that this embodiment of the light-emitting device 100 is a flip-chip light-emitting device in which the light emitted by the active layer 132 is emitted outwardly through the substrate 110. The substrate 110 may be made of a transparent material or a semi-transparent material. In some embodiments, to enhance light extraction from the substrate 110, a thickness of the substrate 110 may be increased. The thickness of the substrate 110 may range from 200 μm to 900 μm (e.g., 200 μm, 400 μm, or 700 μm).

Referring to FIGS. 15 and 16, the light-emitting device 100 may further include a first connection electrode 151, a second connection electrode 152, an insulation layer 160, a first pad electrode 171, and a second pad electrode 172. Specifically, the first connection electrode 151 is formed on the first contact electrode 141, and the second connection electrode 152 is formed on the second contact electrode 142. Each of the first connection electrode 151 and the second connection electrode 152 may be a multilayered metal structure, and may be disposed with an adhesion layer and a conductive layer thereon. The adhesion layer may be made of Cr, and has a thickness that ranges from 1 nm to 10 nm. The conductive layer may be made of Al, and has a thickness that is greater than 100 nm, such as ranging from 200 nm to 500 nm. On one hand, aluminum has a good conductivity, and has high reflectance for ultraviolet light. Furthermore, the conductive layer may be inserted with a stress buffer layer therein, which may be an Al/Ti stacked structure. Moreover, the conductive layer may further be formed with an etch stop layer made of Pt thereon, an adhesion layer made of Ti thereon, etc. The first connection electrode 151 and the second connection electrode 152 may be formed in the same process and have the same multilayered structure. In some embodiments, the first connection electrode 151 covers the first contact electrode 141 completely, which may increase height of the mesa surface (M), and protects the first contact electrode 141 completely.

The insulation layer 160 is formed on the second connection electrodes 152, a side surface of the semiconductor epitaxial structure 130, and the mesa surface (M), so that the first connection electrode 151 and the second connection electrode 152 are insulated. The insulation layer 160 has a first opening 161 and a second opening 162 for exposing a portion of each of the first connection electrode 151 and the second connection electrode 152, respectively. The insulation layer 160 includes a non-conductive material. The non-conductive material may also be an inorganic material or a dielectric material. The inorganic material includes silica gel or glass, and the dielectric material includes aluminum oxide, silicon nitride, silicon oxide, titanium oxide, or magnesium fluoride. For example, the insulation layer 160 may be made of silicon dioxide, silicon nitride, titanium oxide, tantalum oxide, niobium oxide, barium titanate, or combinations thereof which may be, for example, a distributed Bragg reflector (DBR) of two materials that are alternately stacked in a repeated manner. In some embodiments, the insulation layer 160 may be a reflectivity insulation layer. The first pad electrode 171 and the second pad electrode 172 are disposed on the insulation layer 160, and are electrically connected to the first connection electrode 151 and the second connection electrode 152, respectively, through the first opening 161 and the second opening 162, respectively. The first pad electrode 171 and the second pad 172 may be formed in the same process using the same material, and thus may have the same structure. The material of the first pad electrode 171 and the second pad electrode 172 may be selected from Cr, Pt, Au, Ni, Ti, Al, AuSn, or combinations thereof.

In this embodiment, the flip-chip light-emitting device includes the first voids 121 and the second voids 122, which have the needle-like structures and are disposed in the substrate 110 and the AlₓGa₁₋ₓN layer 112. The diameter of each of the first voids 121 and the second voids 122 is smaller than one-half of a wavelength of the light emitted by the active layer 132, and the distance between two adjacent ones of the first voids 121 or two adjacent ones of the second voids 122 is smaller than 1 μm. In this embodiment, when the light emitted from the semiconductor epitaxial structure 130 travels toward the substrate 110, after multiple light coupling and scattering by the first voids 121 and the second voids 122, the light extraction efficiency of the light-emitting device 100 may be effectively increased. Furthermore, by virtue of each of the first voids 121 and each of the second voids 122 having the needle-like structure and an aspect ratio that is no smaller than 2, photons from the active layer 132 may better exit from the light-emitting device 100 in a perpendicular direction, thereby improving the light extraction efficiency and light-emitting concentration of the light-emitting device 100.

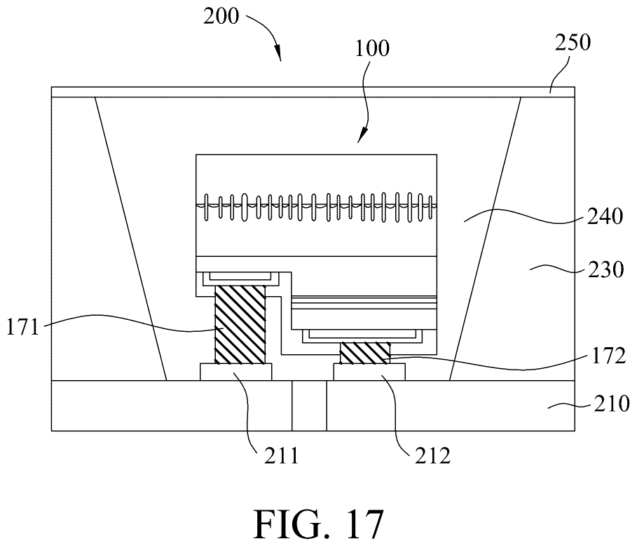

FIG. 17 is a schematic view of a light-emitting apparatus 200 according to the disclosure. Referring to FIG. 17, the light-emitting apparatus 200 includes a packaging frame 210 and the light-emitting device 100 disposed on the packaging frame 210. The light-emitting device may be the light-emitting device shown in FIGS. 1, 13, 15, 16 and 17. The present embodiment is briefly illustrated with the light-emitting device 100 shown in FIG. 17 as an example.

An upper surface of the packaging frame 210 is disposed with a first metal layer 211 and a second metal layer 212 thereon. The first metal layer 211 and the second metal layer 212 are electrically isolated from each other. The first metal layer 211 is electrically connected to the first pad electrode 171 of the light-emitting device 100, and the second metal layer 212 is electrically connected to the second pad electrode 172 of the light-emitting device 100. Furthermore, the upper surface of the packaging frame 210 and a sidewall structure 230 cooperatively form a cavity 240 in which the light-emitting device 100 is sealed within by a cover plate 250. In other embodiments, the light-emitting device 100 is disposed on the upper surface of the packaging frame 210 and then covered by an encapsulation layer (not shown).

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A method for manufacturing a light-emitting device, comprising steps of:
providing a substrate, the substrate having a first surface and a second surface that are opposite to each other;
forming a nucleation layer on the first surface of the substrate by deposition, the nucleation layer having an upper surface that is uneven;
forming a plurality of first voids, the plurality of first voids extending in a direction from the nucleation layer to the substrate, each of the plurality of first voids having an aspect ratio that is greater than 1, and a diameter that is no greater than 300 nm;
forming an AlₓGa₁₋ₓN layer on the nucleation layer to form an even surface, x>0.5; and
forming a semiconductor epitaxial structure on the AlₓGa₁₋ₓN layer.

2. The method as claimed in claim 1, wherein the nucleation layer formed by deposition automatically generates a plurality of high-density dislocations, the plurality of high-density dislocations forming a plurality of pin holes after being subjected to a high-temperature treatment.

3. The method as claimed in claim 2, wherein the nucleation layer is etched along the plurality of pin holes toward the substrate, thereby forming the plurality of first voids.

4. The method as claimed in claim 1, wherein the AlₓGa₁₋ₓN layer is formed with a plurality of second voids in a bottom portion of the AlₓGa₁₋ₓN layer during formation of the AlₓGa₁₋ₓN layer.

5. The method as claimed in claim 4, wherein the plurality of first voids and the plurality of second voids are connected to each other, respectively.

6. A light-emitting device, comprising:
a substrate having a first surface and a second surface that are opposite to each other;
a nucleation layer formed on said first surface of said substrate and having an upper surface that is uneven;
an AlₓGa₁₋ₓN layer formed on said nucleation layer and having an upper surface that is even, x>0.5; and
a semiconductor epitaxial structure formed on said AlₓGa₁₋ₓN layer,
wherein the light-emitting device further comprises a plurality of first voids, said plurality of first voids extending in a direction from said nucleation layer to said substrate, each of said plurality of first voids having an aspect ratio that is greater than 1, and a diameter that is no greater than 300 nm.

7. The light-emitting device as claimed in claim 6, wherein each of said plurality of first voids forms a needle-like structure and has a depth that is no smaller than 50 nm and no greater than 1000 nm.

8. The light-emitting device as claimed in claim 6, wherein said plurality of first voids are randomly distributed and each has a diameter that is smaller than 100 nm.

9. The light-emitting device as claimed in claim 6, wherein, in at least some of said plurality of first voids, a distance between two adjacent ones of said plurality of first voids is smaller than 500 nm.

10. The light-emitting device as claimed in claim 6, wherein said plurality of first voids are spaced apart from and parallel to each other.

11. The light-emitting device as claimed in claim 6, wherein said AlₓGa₁₋ₓN layer is an AlN layer and has a thickness that is greater than 500 nm.

12. The light-emitting device as claimed in claim 6, wherein said AlₓGa₁₋ₓN layer is formed with a plurality of second voids, said plurality of second voids being located in a bottom portion of said AlₓGa₁₋ₓN layer that is proximate to said substrate.

13. The light-emitting device as claimed in claim 12, wherein said plurality of second voids and said plurality of first voids are connected to each other, respectively.

14. The light-emitting device as claimed in claim 6, wherein a distance between each of said plurality of second voids and said nucleation layer is smaller than a distance between each of said plurality of second voids and said semiconductor epitaxial structure.

15. The light-emitting device as claimed in claim 6, wherein said semiconductor epitaxial structure includes a first semiconductor layer, an active layer, and a second semiconductor layer that are sequentially disposed in such order away from said substrate, said AlₓGa₁₋ₓN layer having a thickness that is smaller than a thickness of said first semiconductor layer.

16. The light-emitting device as claimed in claim 6, wherein a distance between each of said plurality of second voids and said semiconductor epitaxial structure is no smaller than 500 nm.

17. A light-emitting device, comprising:
a substrate having a first surface and a second surface that are opposite to each other;
a nucleation layer formed on said first surface of said substrate and having an upper surface that is uneven;
an AlₓGa₁₋ₓN layer formed on said nucleation layer and having an upper surface that is even, x>0.5; and
a semiconductor epitaxial structure formed on said AlₓGa₁₋ₓN layer,
wherein said substrate is formed with a plurality of first voids that are proximate to said first surface, each of said plurality of first voids forming a needle-like structure, and having an end that contacts said first surface and another end that extends towards said second surface, each of said plurality of first voids having a diameter that is greater than 0 and smaller than 100 nm, said AlₓGa₁₋ₓN layer being formed with a plurality of second voids that are distributed in said AlₓGa₁₋ₓN layer.

18. The light-emitting device as claimed in claim 17, wherein each of said plurality of first voids having an aspect ratio that is no smaller than 2.

19. The light-emitting device as claimed in claim 18, wherein each of said plurality of first voids has a depth that is greater than 50 nm and no greater than 2000 nm.

20. The light-emitting device as claimed in claim 17, wherein each of said plurality of second voids has a depth greater than a depth of each of said plurality of first voids.

21. The light-emitting device as claimed in claim 17, wherein a distance between two adjacent ones of at least a portion of said plurality of first voids is no greater than 1 μm.

22. The light-emitting device as claimed in claim 17, wherein said plurality of first voids contact said first surface of said substrate, said plurality of second voids contacting a bottom surface of said AlₓGa₁₋ₓN layer that is proximate to said substrate and being connected to said plurality of first voids, respectively.

23. The light-emitting device as claimed in claim 17, wherein each of said plurality of second voids has an aspect ratio that is greater than 1, said AlₓGa₁₋ₓN layer forming a slit-free even surface facing oppositely from said substrate.

24. A light-emitting apparatus, comprising a packaging substrate and the light-emitting device as claimed in claim 6.
